(19) United States
(12) Patent Application Publication
(10) Pub. No.: US 2020/0080189 A1
(43) Pub. Date: Mar. 12, 2020

(54) ACRYLIC VAPORIZER

(71) Applicants: ULVAC, INC., Chigasaki (JP); SHARP KABUSHIKI KAISHA, Osaka (JP); SAKAI DISPLAY PRODUCTS CORPORATION, Osaka (JP)

(72) Inventors: Yuko KATO, Chigasaki-shi (JP); Satohiro OKAYAMA, Chigasaki-shi (JP); Shuichi OKANO, Chigasaki-shi (JP); Takahiro YAJIMA, Chigasaki-shi (JP); Takashi OCHI, Sakai-shi (JP); Takeshi HIRASE, Sakai-shi (JP); Tsuyoshi SENZAKI, Sakai-shi (JP); Takuji KATO, Sakai-shi (JP); Katsuhiko KISHIMOTO, Sakai-shi (JP); Toru MASUNO, Sakai-shi (JP)

(73) Assignees: ULVAC, INC., Chigasaki-shi (JP); SHARP KABUSHIKI KAISHA, Osaka (JP); SAKAI DISPLAY PRODUCTS CORPORATION, Osaka (JP)

(21) Appl. No.: 16/567,456

(22) Filed: Sep. 11, 2019

(30) Foreign Application Priority Data
Sep. 11, 2018 (JP) 2018-169332

(51) Int. Cl. C23C 14/22; C23C 14/12

(52) U.S. Cl. CPC C23C 14/228; C23C 14/12

(57) ABSTRACT

A flow resistant part having a rod shape is disposed in a raw liquid introduction path in a manner such that the raw liquid is sprayed onto a vaporization plate to reduce the conductance of the raw liquid introduction path with respect to the raw liquid. Because the pressure on an outlet side of the liquid mass flow controller is increased, and the pressure difference from the pressure on the inlet side of the liquid mass flow controller is reduced, the occurrence of cavitation can be prevented. A plurality of the flow resistant parts can be provided.

### BACKGROUND

The present invention generally relates to a technique for vaporizing an acrylic resin raw material, and more particularly to a technique for stabilizing a gas generation rate of the acrylic resin raw material.

For example, an organic Electro Luminescence (EL) element or the like is known as an element including a compound that easily deteriorates due to moisture or oxygen. For such an element, an attempt has been made to suppress intrusion of moisture or the like into the element by forming a lamination layer structure of a layer containing the compound and a protective layer covering the layer. For example, JPA 2013-73880 describes a light-emitting element having a protective layer composed of a laminated film made of an inorganic film and an organic film on an upper electrode layer.

When forming an acrylic resin thin film, a raw liquid of the acrylic resin is vaporized with an acrylic vaporizer to generate a source gas. Then, the source gas is supplied to and deposited on a surface of an object to be film formed and then, the object to be film formed is heated to polymerize the acrylic resin raw material to form an acrylic resin film.

In order to stabilize the film formation rate of the acrylic resin thin film, it is necessary to stabilize the supply rate of the source gas. Therefore, a liquid mass flow controller (MFC) is provided between the acrylic vaporizer and a raw material tank so that a raw liquid controlled in flow rate by the liquid mass flow controller is supplied to the acrylic vaporizer.

However, the amount of the acrylic resin raw material supplied from the liquid mass flow controller may fluctuate instantaneously, which may cause a problem in the case of short-time film formation.

When observing the liquid-state acrylic resin raw material supplied to the acrylic vaporizer from the liquid mass flow controller, it was found that cavitation occurred in the acrylic resin raw material due to the pressure difference, and it was confirmed that the cause of the instantaneous fluctuation of the amount of the acrylic resin raw material supplied from the liquid mass flow controller was the cavitation.

The cavitation is considered to be caused by one of the fact that the pressure gas used to supply the raw liquid from the raw material tank is dissolved in the raw liquid. Therefore, it is conceivable that gas having low solubility is used for the pressure gas.

It is also conceivable to provide a vacuum degassing device between the liquid mass flow controller and the raw material tank so as to remove the gas dissolved in the raw liquid.

However, these measures are not desirable because they are expensive and increase the time and effort for management.

### SUMMARY

An object of the present invention is to provide an inexpensive and reliable technique that does not cause cavitation in a liquid-state acrylic resin raw material supplied from a liquid mass flow controller.

In order to solve the above-mentioned problems, the present embodiment provides an acrylic vaporizer including a raw liquid introduction path through which a raw liquid of an acrylic resin film controlled in flow rate by a liquid mass flow controller flows, a spout where the raw liquid that has flowed through the raw liquid introduction path reaches, a carrier gas introduction path configured to supply a carrier gas to the spout, a sealed container having an internal space in which fine droplets of the raw liquid and the carrier gas are discharged through the spout, a vaporization plate disposed in the internal space, and to be in contact with the fine droplets of the raw liquid, a heating device for heating the vaporization plate, and a source gas supply pipe through which a source gas generated by the fine droplets being in contact with the vaporization plate heated by the heating device flows, and the source gas is a gas of the raw liquid, wherein a flow resistant part having a rod shape is disposed in the raw liquid introduction path, and a conductance of the raw liquid introduction path with respect to the raw liquid is reduced by flowing the raw liquid through a gap between the flow resistant part and a wall surface of the raw liquid introduction path.

The present embodiment of the acrylic vaporizer further includes a raw liquid introduction pipe provided in the sealed container, and a nozzle device provided on a wall surface facing the internal space of the sealed container, wherein the raw liquid introduction path is formed of connecting a first liquid introduction hole provided in the raw liquid introduction pipe, a second liquid introduction hole provided in the ceiling of the sealed container, and a third liquid introduction hole provided in the nozzle device, and the flow resistant part is disposed in an interior of at least one of the first to the third liquid introduction holes.

The present embodiment of the acrylic vaporizer also has the flow resistant part divided into at least two. The present embodiment of the acrylic vaporizer also has an outer diameter of the flow resistant part having a rod shape that is smaller than an inner diameter of the raw liquid introduction path.

Furthermore, the present embodiment of the acrylic vaporizer also has the flow resistant part disposed on a support member provided in the interior of the raw liquid introduction path.

Because the occurrence of cavitation can be prevented, the generation rate of the source gas for the acrylic resin film can be stabilized.

### BRIEF DESCRIPTION OF DRAWINGS

FIG. 1 is a block diagram for explaining an acrylic resin film manufacturing apparatus in which an acrylic vaporizer of the present embodiment is used; and

FIG. 2 shows the acrylic vaporizer of the present embodiment.

### DETAILED DESCRIPTION

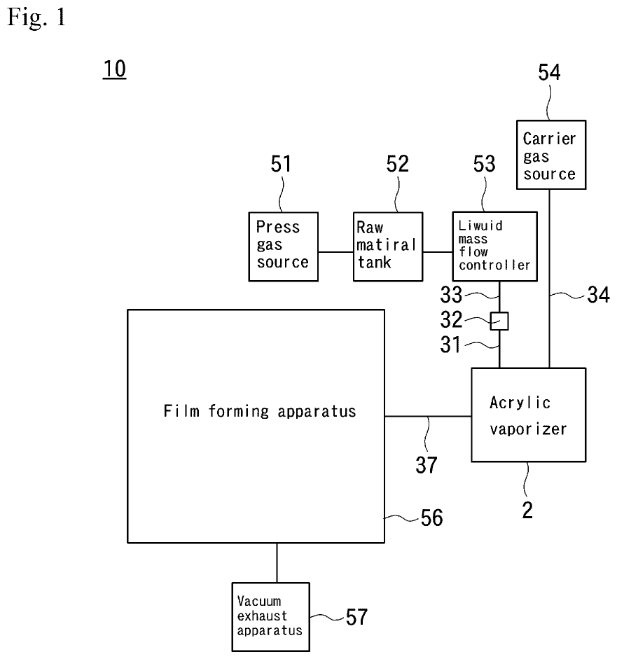

FIG. 1 is a block diagram for explaining an acrylic resin film manufacturing apparatus 10 for forming an acrylic resin film. A raw material for forming an acrylic resin film on a surface of a processing object used in the present embodiment is a liquid-state monomer, which is a raw liquid from which a polymer acrylic resin is obtained when polymerized.

The raw liquid is stored in a raw material tank 52. First, the outline of the operation of the acrylic resin film manufacturing apparatus 10 will be described. The raw material tank 52 is connected to the acrylic vaporizer 2 via the liquid mass flow controller 53. When the raw liquid stored in the raw material tank 52 is supplied to the acrylic vaporizer 2 in a state in which the flow rate is controlled by the liquid mass flow controller 53, the liquid-state raw liquid is vaporized in the interior of the acrylic vaporizer 2 to generate a gas-state source gas, which is a raw material of the acrylic resin.

An object to be film formed is disposed in an interior of a film forming apparatus 56, and the interior of the film forming apparatus 56 is vacuum evacuated by a vacuum exhaust device 57.

The source gas generated by the acrylic vaporizer 2 is supplied to the film forming apparatus 56, adheres to the object to be film formed, and is polymerized by curing means such as heating of the object to be film formed or ultraviolet irradiation onto the object to be film formed so as to form an acrylic resin film on the surface of the object to be film formed.

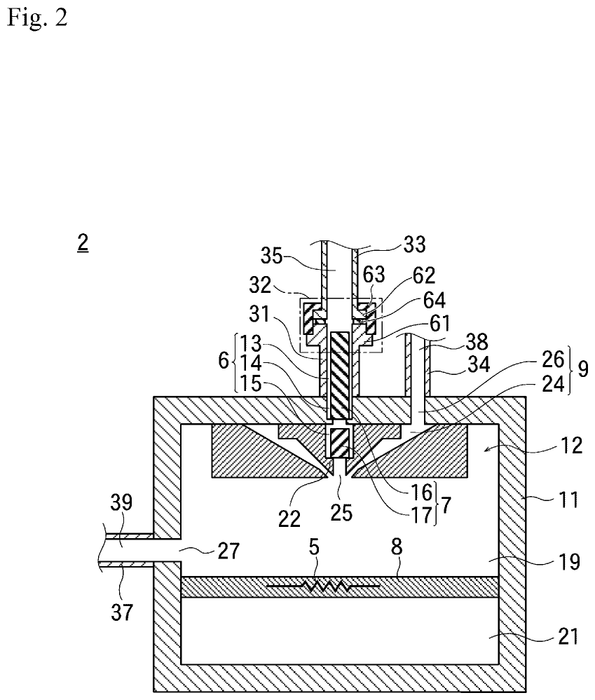

Next, the operation of the acrylic vaporizer 2 will be described. Referring to FIG. 2, the acrylic vaporizer 2 has a sealed container 11, and a raw liquid introduction pipe 31 and a carrier gas transporting pipe 34, and a source gas supply pipe 37 are provided outside the sealed container 11.

A first liquid introduction hole 13 is formed in an interior of the raw liquid introduction pipe 31, and a second liquid introduction hole 14, a first gas introduction hole 26, and a source gas supply hole 27 are formed in the wall of the sealed container 11. The wall of the sealed container 11 includes also a ceiling and a bottom plate in addition to the side wall. Here, the second liquid introduction hole 14 and the first gas introduction hole 26 are provided in the ceiling, and the source gas supply hole 27 is provided in the side wall. However, the positions of the holes are not limited thereto.

Then, one end of the raw liquid introduction pipe 31 is fixed to the sealed container 11 in a manner such that the first liquid introduction hole 13 and the second liquid introduction hole 14 are connected each other, and the other end of the raw liquid introduction pipe 31 is connected to the connecting portion 32. The other end of the raw liquid transport pipe 33, one end of which is connected to a liquid mass flow controller 53, is connected to the connecting portion 32, and a liquid general piping hole 35 in the interior of the raw liquid transport pipe 33 and the first liquid introduction hole 13 of the raw liquid introduction pipe 31 are in communication with each other at the connecting portion 32.

In the connecting portion 32, a flange 61 formed at the other end of the raw liquid introduction pipe 31 and a flange 62 formed at the other end of the raw liquid transport pipe 33 are in close contact with each other via a metal gasket 64. A cap 63 having a screw is attached to these two flanges 61 and 62, so that the two flanges 61 and 62 are pressed against with each other by the cap 63. By this structure, there is no liquid leakage at the connecting portion 32.

Note that the raw liquid introduction pipe 31 is fixed to the sealed container 11. When removing the acrylic vaporizer 2 from the raw liquid transport pipe 33, the cap 63 of the connecting portion 32 is loosened, and the raw liquid introduction pipe 31 is separated from the raw liquid transport pipe 33 while the raw liquid introduction pipe 31 is fixed to the sealed container 11.

A gas pipe hole 38 is formed in an interior of the carrier gas transporting pipe 34, and one end of the carrier gas transporting pipe 34 is fixed to the sealed container 11 in a manner such that the gas pipe hole 38 and the first gas introduction hole 26 are connected with each other. The other end of the carrier gas transporting pipe 34 is connected to a carrier gas source 54, and the carrier gas supplied from the carrier gas source 54 reaches the first gas introduction hole 26 through the gas pipe hole 38.

A source gas introduction hole 39 is disposed in the source gas supply pipe 37. One end of the source gas supply pipe 37 is connected to the sealed container 11 so that the source gas introduction hole 39 and the source gas supply hole 27 are connected with each other. The other end of the source gas supply pipe 37 is connected to the film forming apparatus 56, and the source gas is supplied to the film forming apparatus 56 through the source gas introduction hole 39.

Next, transportation of the raw liquid will be discussed.

A pressing gas source 51 is connected to the raw material tank 52. When the pressure gas is supplied from the pressing gas source 51 to the raw material tank 52, the raw liquid stored in the raw material tank 52 is pressed by the pressing gas so that the raw liquid flows through the pipe and reaches the liquid mass flow controller 53.

The liquid mass flow controller 53 is configured to control the flow rate of the liquid flowing in the interior thereof, and the raw liquid that has reached the liquid mass flow controller 53 is controlled in flow rate in an interior of the liquid mass flow controller 53, so that a constant amount of the raw liquid per unit time passes through the liquid mass flow controller 53.

The raw liquid of which the flow rate is controlled by the liquid mass flow controller 53, is introduced into the liquid general piping hole 35 in the interior of the raw liquid transport pipe 33, and is introduced from the liquid general piping hole 35 into the first liquid introduction hole 13 in an interior of the raw liquid introduction pipe 31 in the connecting portion 32, flows through the first liquid introduction hole 13, and moves to the second liquid introduction hole 14.

An internal space 19 is formed in an interior of the sealed container 11, and a nozzle device 12 is fixed to the wall surface of the sealed container 11 on the internal space 19 side. Here, the nozzle device 12 is provided on a wall surface of the ceiling side of the sealed container 11.

In an interior of the nozzle device 12, a third liquid introduction hole 15 and a second gas introduction hole 24 are formed, and the third liquid introduction hole 15 is arranged at a position communicating with the second liquid introduction hole 14. The second gas introduction hole 24 is disposed at a position communicating with the first gas introduction hole 26.

The carrier gas that has reached the first gas introduction hole 26 moves into the second gas introduction hole 24 through the first gas introduction hole 26.

A spout 25 is disposed at the lower end of the second gas introduction hole 24, and the carrier gas that has flowed through the second gas introduction hole 24 reaches the spout 25 and spouts into the internal space 19.

The position of the spout 25 is also the lower end of the third liquid introduction hole 15, and the raw liquid that has flowed through the second liquid introduction hole 14 moves to the third liquid introduction hole 15 and flows through the third liquid introduction hole 15. When the raw liquid reaches the spout 25, it is blown off by the carrier gas that has reached the spout 25, and the raw liquid spouts into the internal space 19 of the sealed container 11 through the spout 25 in the form of the mist-like fine droplets together with the carrier gas.

Next, the vaporization of the raw liquid will be discussed. The vaporization plate 8 is disposed in a lower part of the internal space 19. The vaporization plate 8 is provided with a heating device 5 that generates heat when energized. When the heating device 5 generates heat, the vaporization plate 8 is heated. The front surface side of the vaporization plate 8 faces the nozzle device 12, and a storage portion 21 is provided on the back surface side. Excess raw liquid or the like falls into the storage portion 21.

The fine droplets of the mist-like raw liquid discharged from the spout 25 into the internal space 19 move in the internal space 19 toward the vaporization plate 8, and reach the vaporization plate 8. When the fine droplets of the raw liquid come into contact with the vaporization plate 8, the temperature rises and vaporizes, and source gas which is vapor of the raw liquid, is generated.

The first gas introduction hole 26 and the second gas introduction hole 24 function as a carrier gas introduction path 9 between the carrier gas transporting pipe 34 and the spout hole 25.

The first to third liquid introduction holes 13 to 15 are arranged in line in the vertical direction with the first liquid introduction hole 13 disposed at the uppermost position and the third liquid introduction hole 15 disposed at the lowermost position. When the source gas is generated in the acrylic vaporizer 2, the raw liquid is moves through the first to third liquid introduction holes 13 to 15 of the acrylic vaporizer 2 as a passage before reaching the spout 25 from the raw liquid transport pipe 33. Therefore, in the interior of the acrylic vaporizer 2, the first to third liquid introduction holes 13 to 15 function as one vertical raw liquid introduction path 6.

A flow resistant part 7 having a rod shape is arranged in an interior of the raw liquid introduction path 6.

Here, the flow resistant part 7 may be composed of first to third column bodies having a rod shape and being respectively disposed in the first liquid introduction hole 13, the second liquid introduction hole 14, and the third liquid introduction hole 15.

As shown in FIG. 2, the first to third column bodies may be formed of a single joined column body 16 in which the first column body and the second column body are joined. In that case, the joined column body 16 is disposed across the first liquid introduction hole 13 and the second liquid introduction hole 14, and the third column body 17 is disposed in the third liquid introduction hole 15. The first to third column bodies may be disposed separately in the first to third liquid introduction holes 13 to 15, respectively, and the column body or column bodies disposed in any one or more of the first to third liquid introduction holes 13 to 15 can be used as the flow resistant part 7.

The raw liquid introduction path 6 is circular in cross section, the first to third columnar bodies have a cylindrical shape and are arranged vertically. The diameters of the bottom surfaces of the first to third column bodies are smaller than the diameters of the first to third liquid introduction holes 13 to 15 where the columns are disposed. Therefore, gaps are respectively formed between the side surfaces of the first to third column bodies and the inner peripheral surfaces of the first to third liquid introduction holes 13 to 15 where the column bodies are disposed.

The point being that, the circular cross-sectional shape of the flow resistant part 7 is smaller than the circular cross-sectional shape of the raw liquid introduction path 6. Therefore, among the first to third liquid introduction holes 13 to 15 which constitutes the raw liquid introduction path 6, when an inner peripheral side surface of the raw liquid introduction pipe 31, which constitutes a wall surface of the first liquid introduction hole 13, a ceiling member of the sealed container 11 which constitutes the wall surface of the second liquid introduction hole 14, and a member which constitutes the nozzle device 12 which constitutes a wall surface of the third liquid introduction hole 15 face the side surface of the flow resistant part 7, gaps are formed between these members and the flow resistant part 7, and the raw liquid flows through these gaps.

In the case where the flow resistant part 7 is disposed in the raw liquid introduction path 6, the raw liquid hardly moves through the raw liquid introduction path 6, as compared to the case where the flow resistant part 7 is not disposed, so that the conductance of the raw liquid introduction path 6 relative to the movement of the raw liquid is smaller than when the flow resistant part 7 is not disposed. The cross-sectional shape of the flow resistant part 7 only needs to be smaller than the cross-sectional shape of the raw liquid introduction path 6, and the cross-sectional shape of the flow resistant part 7 and the cross-sectional shape of the raw liquid introduction path 6 are not limited to a circular shape.

The flow resistant part 7 is only required to be inserted into the raw liquid introduction path 6, and the outer diameter of the flow resistant part 7 having a rod shape only needs to be smaller than the inner diameter of the raw liquid introduction path 6.

Further, a part of the raw liquid introduction path 6 having a reduced inner diameter smaller than an outer diameter of the flow resistant part 7 is used as a support member, the flow resistant part 7 is arranged on the support member in a manner such that the flow resistant part 7 is prevented from falling. Furthermore, when a convex portion is provided on a part of the inner peripheral surface of the raw liquid introduction path 6, the flow resistant part 7 is disposed on the convex portion as a support member so that the flow resistant part 7 does not fall. Reference numeral 22 in FIG. 2 denotes a support member formed of a convex portion. The support 22 having a convex portion or small diameter has such a structure that the raw liquid is passed between a plurality of the support members 22 with the flow resistant part 7 disposed therebetween to secure the flow path of the raw liquid.

By disposing the flow resistant part 7 inside the raw liquid introduction path 6, the pressure at the connected portion between the liquid mass flow controller 53 and the raw liquid transport pipe 33 is higher than that when the flow resistant part 7 is not disposed. Therefore, the pressure difference between both ends of the liquid mass flow controller 53 is reduced. By reducing the pressure difference, the occurrence of cavitation is prevented, and bubbles do not intrude the interior of the acrylic vaporizer 2, so that the generation rate for generating the source gas from the raw liquid becomes more stable.

The source gas vaporized at a stable production rate is supplied to the film forming apparatus 56 through the source gas supply hole 27 of the source gas supply pipe 37, is attached to the object to be film formed, and is polymerized by curing means, such as, heating, and thus, an acrylic resin film is formed.

By adopting a structure in which the flow resistant part 7 can be inserted as in the embodiment of the present invention, the length and diameter of the flow resistant part 7 can be easily changed. That is, by changing the flow resistant part 7 to a different shape, the pressure at the connection portion between the liquid mass flow controller 53 and the raw liquid transport pipe 33 can be easily adjusted. The shape of the flow resistant part 7 includes the length of the flow resistant part 7 in addition to the shape of the cross-sectional area.

What is claimed is:

1. An acrylic vaporizer comprising:
a raw liquid introduction path through which a raw liquid of an acrylic resin film controlled in flow rate by a liquid mass flow controller flows;
a spout where the raw liquid that has flowed through the raw liquid introduction path reaches;
a carrier gas introduction path configured to supply a carrier gas to the spout;
a sealed container having an internal space in which fine droplets of the raw liquid and the carrier gas are discharged through the spout;
a vaporization plate disposed in the internal space, and disposed to be in contact with the fine droplets of the raw liquid;
a heating device for heating the vaporization plate; and
a source gas supply pipe through which a source gas generated by the fine droplets being in contact with the vaporization plate heated by the heating device flows, and the source gas is a gas of the raw liquid,
wherein a flow resistant part having a rod shape is disposed in the raw liquid introduction path, and a conductance of the raw liquid introduction path with respect to the raw liquid is reduced by flowing the raw liquid through a gap between the flow resistant part and a wall surface of the raw liquid introduction path.

2. The acrylic vaporizer according to claim 1, further comprising:
a raw liquid introduction pipe provided in the sealed container; and
a nozzle device provided on a wall surface facing the internal space of the sealed container,
wherein the raw liquid introduction path is formed of connecting a first liquid introduction hole provided in the raw liquid introduction pipe, a second liquid introduction hole provided in the ceiling of the sealed container, and a third liquid introduction hole provided in the nozzle device, and
the flow resistant part is disposed in an interior of at least one of the first to the third liquid introduction holes.

3. The acrylic vaporizer according to claim 2, wherein the flow resistant part is divided into at least two.

4. The acrylic vaporizer according to claim 2, wherein an outer diameter of the flow resistant part having a rod shape is smaller than an inner diameter of the raw liquid introduction path.

5. The acrylic vaporizer according to claim 4, wherein the flow resistant part is disposed on a support member provided in the interior of the raw liquid introduction path.
